(19) United States
(12) Patent Application Publication
(10) Pub. No.: US 2026/0096405 A1
(43) Pub. Date: Apr. 2, 2026

(54) Via and Redistribution Layer Formation Process for Glass Interposer

(71) Applicant: Applied Materials, Inc., Santa Clara, CA (US)

(72) Inventors: Sarah WOZNY, Austin, TX (US); Marvin Louis BERNT, Whitefish, MT (US)

(21) Appl. No.: 18/901,939

(22) Filed: Sep. 30, 2024

(51) Int. Cl. H01L 21/768

(52) U.S. Cl. CPC H10W 20/057; H10W 20/042

(57) ABSTRACT

Methods and apparatus for processing a substrate are provided herein. In some embodiments, a method of processing a substrate includes: forming a first patterned mask on a substrate made of glass; etching exposed portions of the substrate to form a plurality of blind vias; removing the first patterned mask; forming a second patterned mask on the substrate after removing the first patterned mask; etching exposed second portions of the substrate to form a redistribution layer (RDL) pattern at an upper portion of at least one of the plurality of blind vias; depositing a seed layer in the plurality of blind vias and the RDL pattern; and filling the plurality of blind vias and the RDL pattern with a metal material to form a plurality of filled vias and a redistribution layer (RDL).

### FIELD

Embodiments of the present disclosure generally relate to substrate processing equipment.

### BACKGROUND

As electronic products become smaller and lighter with an increasing number of functions, the demand for high density and high bandwidth interconnections is becoming stronger. The concept of 2.5-D and 3-D integrated circuit (IC) integration for packaging is a key component to achieving next-generation performance requirements. An ultrahigh number of I/O connections is becoming available using interposers. One of the most prominent and widely used type of interposers are through silicon vias interposers. However, TSV interposers are limited by high cost and high electrical loss. On the other hand, glass has many properties that make glass an ideal substrate for interposer substrates such as: ultra-high resistivity, adjustable thermal expansion (CTE), and manufacturability with large panel size. Conventional via formation in glass is conducted using a laser and wet etch process to create a through glass via opening.

However, the through glass via opening results in issues with seed layer uniformity at a center of each of the vias and step coverage on the sidewalls of the vias. Further, such processing generally limits via diameters to 50 micrometers or greater. Accordingly, the inventors have provided herein embodiments of improved methods to process a substrate.

### SUMMARY

Methods and apparatus for processing a substrate are provided herein. In some embodiments, a method of processing a substrate includes: forming a first patterned mask on an upper surface of a substrate made of glass, wherein openings of the first patterned mask expose portions of the substrate; etching the exposed portions of the substrate to form a plurality of blind vias; removing the first patterned mask; forming a second patterned mask on the substrate after removing the first patterned mask, wherein openings of the second patterned mask expose second portions of the substrate; etching the exposed second portions of the substrate to form a redistribution layer (RDL) pattern at an upper portion of at least one of the plurality of blind vias; depositing a seed layer in the plurality of blind vias and the RDL pattern; and filling the plurality of blind vias and the RDL pattern with a metal material to form a plurality of filled vias and a redistribution layer (RDL).

In some embodiments, a method of processing a substrate includes: etching the substrate to form a plurality of blind vias; etching the substrate to form a redistribution layer (RDL) pattern at an upper portion of at least one of the plurality of blind vias; depositing a seed layer in the plurality of blind vias and the RDL pattern; and filling the plurality of blind vias and the RDL pattern with a metal material to form a plurality of filled vias and a redistribution layer (RDL).

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow chart of a method 100 of processing a substrate in accordance with at least some embodiments of the present disclosure.

FIG. 2 depicts a side view of a portion of a substrate after forming a first patterned mask in accordance with at least some embodiments of the present disclosure.

FIG. 3 depicts a side view of a portion of a substrate after forming a plurality of blind vias in accordance with at least some embodiments of the present disclosure.

FIG. 4 depicts a side view of a portion of a substrate after forming a second patterned mask on the substrate in accordance with at least some embodiments of the present disclosure.

FIG. 5 depicts a side view of a portion of a substrate after forming a redistribution layer (RDL) pattern in accordance with at least some embodiments of the present disclosure.

FIG. 6 depicts a side view of a portion of a substrate after removing the second patterned mask in accordance with at least some embodiments of the present disclosure.

FIG. 7 depicts a side view of a portion of a substrate after depositing a seed layer in accordance with at least some embodiments of the present disclosure.

FIG. 8 depicts a side view of a portion of a substrate after filling the plurality of blind vias and forming a redistribution layer in accordance with at least some embodiments of the present disclosure.

FIG. 9 depicts a side view of a portion of a substrate after performing a planarization process on the upper surface of the substrate after forming a plurality of filled vias in accordance with at least some embodiments of the present disclosure.

FIG. 10 depicts a side view of a portion of a substrate after attaching a second redistribution layer and carrier plate to an upper surface of the substrate in accordance with at least some embodiments of the present disclosure.

FIG. 11 depicts a side view of a portion of a substrate after removing a lower portion of the substrate to expose a plurality of filled vias in accordance with at least some embodiments of the present disclosure.

FIG. 12 depicts a side view of a portion of a substrate after forming a redistribution layer on a lower portion of the substrate in accordance with at least some embodiments of the present disclosure.

FIG. 13 depicts a side view of a portion of a substrate after removing a carrier plate in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of methods of processing a substrate, such as a glass substrate, are provided herein. The methods provided herein may advantageously be used to fill glass through vias having a diameter below about 20 micrometers. Blind vias generally refer to vias that extend only a portion of a way through the substrate. The methods provided herein include forming a blind via in a substrate to advantageously provide a floor, or bottom surface defined by the blind via, for supporting a seed layer to be deposited along the sidewalls and the floor defined by the blind via, leading to enhanced seed layer uniformity in the blind via. The substrate may also advantageously have a larger form factor than traditional 300 mm wafers, such as a rectangular or square form factor that exceeds 300 mm, to enable technology scaling and cost reduction. The methods provided herein may also advantageously be used to fill the blind via and form a redistribution layer (RDL) in a single step, although additional steps may be used in some embodiments.

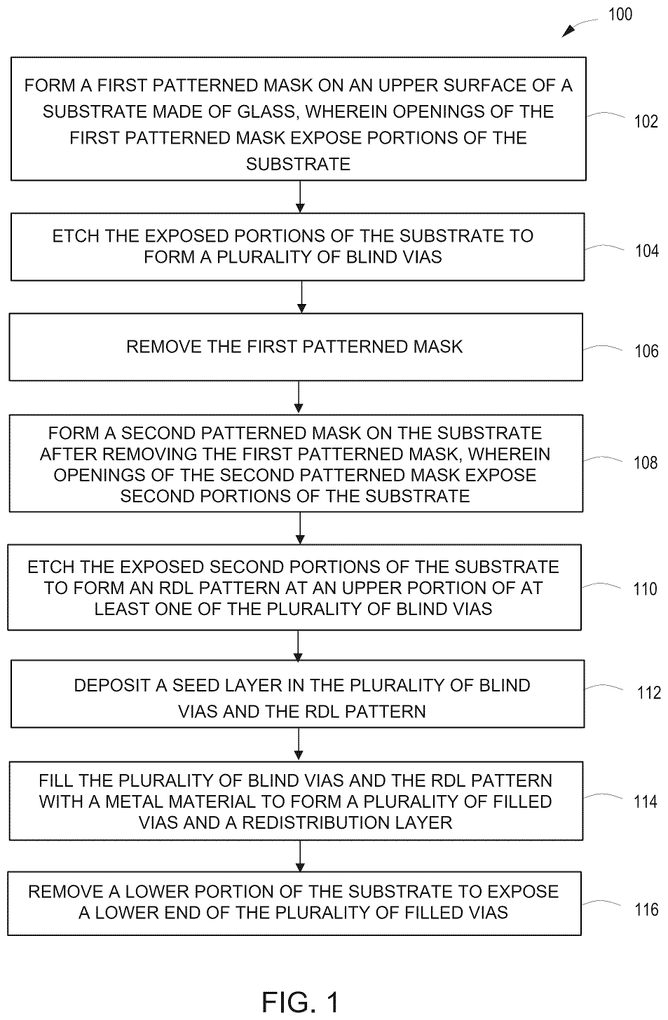

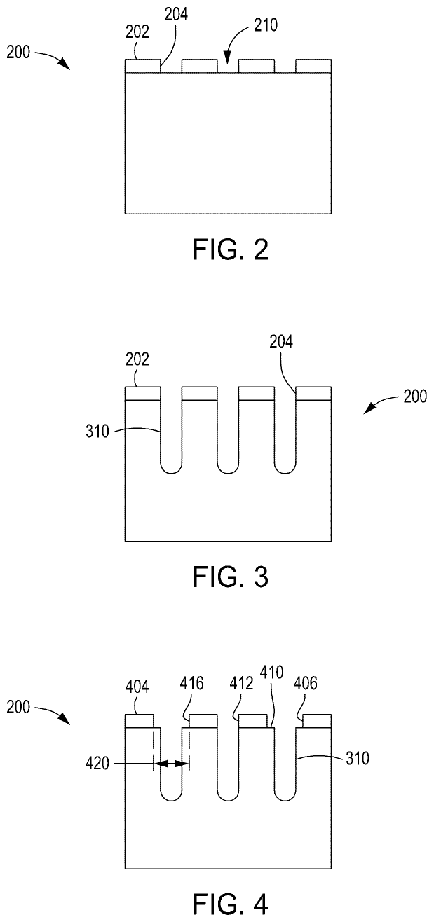

FIG. 1 depicts a flow chart of a method 100 of processing a substrate in accordance with at least some embodiments of the present disclosure. At 102, the method 100 includes forming a first patterned mask on an upper surface of a substrate made of glass, as shown in FIG. 2. FIG. 2 depicts a side view of a portion of a substrate 200 after forming a first patterned mask 202 in accordance with at least some embodiments of the present disclosure. In some embodiments, the first patterned mask 202 is formed via lithography. Openings 204 of the first patterned mask 202 expose portions 210 of the substrate 200. In some embodiments, the substrate 200 has a rectangular shape or square shape. In some embodiments, the substrate 200 has a thickness of about 0.6 to about 1.5 mm, for example, about 0.8 to about 1.3 mm.

At 104, the method 100 includes etching the exposed portions 210 of the substrate 200 to form a plurality of blind vias 310, as shown in FIG. 3. FIG. 3 depicts a side view of a portion of a substrate 200 after forming the plurality of blind vias 310 in accordance with at least some embodiments of the present disclosure. The plurality of blind vias 310 extend only partially through the substrate 200. In some embodiments, etching the exposed portions 210 comprises a dry etch process. For example, the dry etch may comprise removal of material using plasma as opposed to chemical treatment. In some embodiments, etching does not include laser drilling. Dry etching may provide higher resolution dimensions for the plurality of blind vias 310 compared to laser drilling. In some embodiments, the plurality of blind vias 310 have a diameter of less than about 20 microns.

At 106, the method 100 includes removing the first patterned mask 202. Removing the first pattern mask 202 may be performed via a suitable process, for example, an ashing process or chemical process. The ashing process may generally refer to a process of removing the first patterned mask 202 by exposing the substrate 200 to a plasma of reactive gases, such as oxygen (O₂), which may react with photoresist material of the first patterned mask 202. The reaction between the plasma of reactive gases and the photoresist material breaks down the long-chain polymer structure of the photoresist into smaller compounds, essentially oxidizing and removing the first patterned mask 202 from the substrate 200.

At 108, the method 100 includes forming a second patterned mask 404 on the substrate 200 after removing the first patterned mask 202, as shown in FIG. 4. In some embodiments, openings 406 of the second patterned mask 404 expose second portions 410 of the substrate 200. In some embodiments, the second patterned mask 404 is formed via lithography. The second patterned mask 404 has a different pattern than the first patterned mask 202. In some embodiments, the openings 406 of the second patterned mask 404 comprises a combination of a plurality of circular openings 412 corresponding with a size of the plurality of blind vias 310 and a plurality of elongate openings 416 extending across multiple vias of the plurality of blind vias 310. A width 420 of the plurality of elongate openings 416 is greater than the diameter of the plurality of blind vias 310. In some embodiments, the plurality of elongate openings 416 may be sized and arranged to define a pattern of an RDL layer to be formed in the substrate 200.

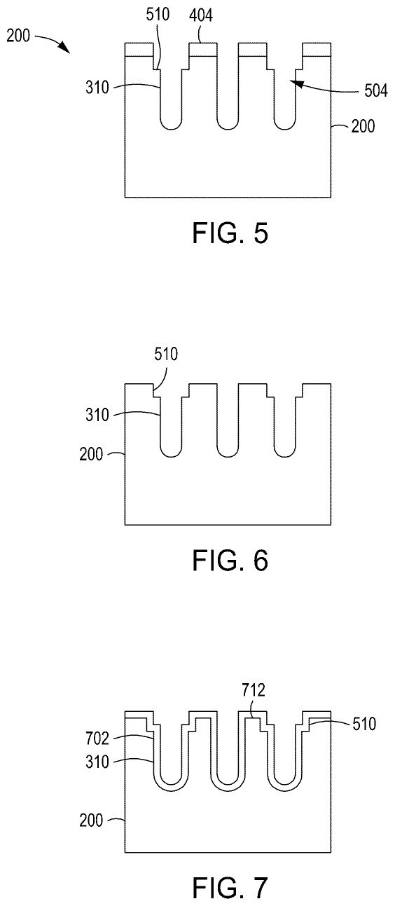

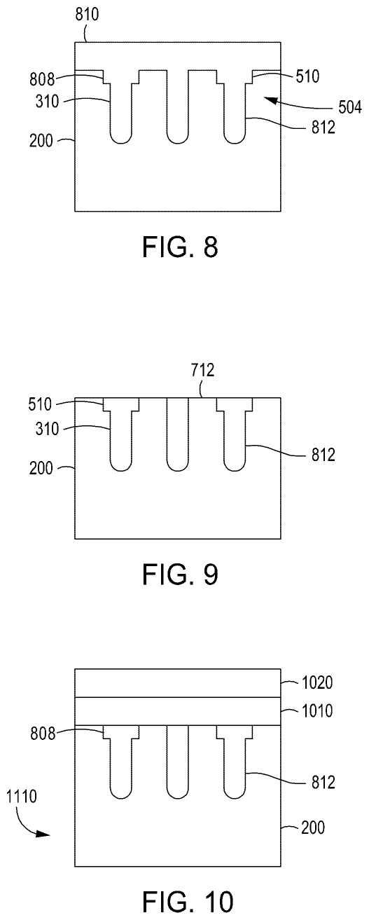

At 110, the method 100 includes etching the exposed second portions 410 of the substrate 200 to form a redistribution layer (RDL) pattern 510 that is recessed along an upper surface of the substrate and at an upper portion 504 of at least one of the plurality of blind vias 310, as shown in FIG. 5. For example, the RDL pattern 510 forms a pattern for a redistribution layer to be formed (see FIG. 8). FIG. 5 depicts a side view of a portion of a substrate 200 after forming the RDL pattern 510 in accordance with at least some embodiments of the present disclosure. In some embodiments, the RDL pattern 510 overlaps with a plurality of the blind vias 310. For example, in some embodiments, the RDL pattern 510 may extend linearly (e.g., into or out of the page in the side view of FIG. 5) and overlap with multiple ones of the plurality of blind vias 310 when considering the substrate 200 in a three-dimensional form. In some embodiments, the RDL pattern 510 may comprise discontinuous recesses, where each recess overlaps with one or more of the plurality of blind vias 310.

In some embodiments, etching the exposed portions 210 comprises a dry etch process. After the forming the RDL pattern 510, the method 100 includes removing the second patterned mask 404. Removing the second patterned mask 404 may be performed via a suitable process, for example, an ashing process (via plasma) or chemical process. FIG. 6 depicts a side view of a portion of the substrate 200 after removing the second patterned mask 404 in accordance with at least some embodiments of the present disclosure.

At 112, the method 100 includes depositing a seed layer 702 in the plurality of blind vias 310 and the RDL pattern 510, as shown in FIG. 7. The seed layer may advantageously be deposited in the plurality of blind vias 310 and the RDL pattern 510, and an upper surface 712 of the substrate 200 in a one step process. FIG. 7 depicts a side view of a portion of a substrate 200 after depositing the seed layer 702 in accordance with at least some embodiments of the present disclosure. In some embodiments, the seed layer 702 is deposited via a physical vapor deposition process. In some embodiments, the seed layer 702 is made of metal, such as copper.

At 114, the method 100 includes filling the plurality of blind vias and the RDL pattern with a metal material to form a plurality of filled vias 812 and a redistribution layer (RDL) 808, as shown in FIG. 8. The plurality of filled vias 812 and the RDL 808 may be formed from the same metal material. The RDL 808, also known as redistribution line or redistribution wiring, is an integral component of advanced packaging techniques used in microelectronics. During the manufacturing process of an integrated circuit, there typically is a set of I/O pads that are wire bonded to the package pins. The inclusion of the RDL 808 allows for the creation of additional wiring, enabling the redistribution of the I/O pads to different locations. FIG. 8 depicts a side view of a portion of a substrate 200 after filling the plurality of blind vias 310 in accordance with at least some embodiments of the present disclosure.

In some embodiments, filling the plurality of blind vias 310 is performed via a plating process. In some embodiments, the seed layer 702 and the metal material 810 comprise copper. In some embodiments, the plating process may fill the plurality of blind vias 310, fill the RDL pattern 510 to form the RDL 808, and deposit a layer of material on the seed layer 702 atop the upper surface 712 of the substrate 200. In some embodiments, filling the RDL pattern 510 and filling the plurality of blind vias 310 may be performed in a single process, e.g., a single deposition process that fills the plurality of blind vias 310 and the RDL pattern 510.

In some embodiments, the method 100 includes planarizing the upper surface 712 of the substrate 200. FIG. 9 depicts a side view of a portion of a substrate after performing the planarization process on the upper surface 712 of the substrate 200 after forming the plurality of filled vias 812 and the RDL 808 in accordance with at least some embodiments of the present disclosure. In some embodiments, after the planarization process, a first set of the plurality of filled vias 812 remain electrically coupled via the RDL 808.

In some embodiments, the method 100 includes forming a second RDL 1010 on the upper surface 712 of the substrate 200, as shown in FIG. 10. The second RDL 1010 may include redistribution wiring that interfaces with the RDL 808 to enable further redistribution of the I/O pads to different locations.

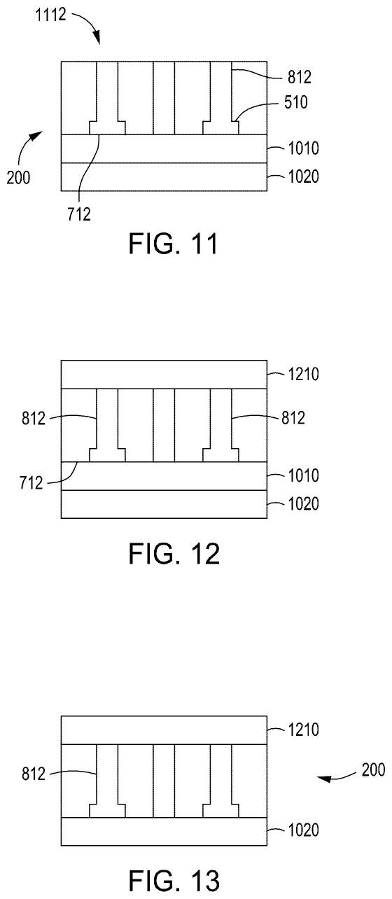

In some embodiments, the method 100 includes attaching a carrier plate 1020 to the substrate 200 prior to removing the lower portion 1005 of the substrate 200, as shown in FIG. 10. In some embodiments, the carrier plate 1020 comprises glass or metal such as steel. The carrier plate 1020 provides structural support for the substrate 200 for subsequent processes (for example, removing a lower portion of the substrate 200). Optionally, at 116, the method 100 can include removing a lower portion of the substrate to expose a lower end 1112 of the plurality of filled vias, as depicted in FIG. 11. In some embodiments, the substrate 200 may be rotated prior to removing the lower portion 1110. For example, as shown in FIG. 11, the substrate 200 can be rotated 180 degrees (e.g., flipped top to bottom) and the lower portion 1110 of the substrate 200 can be removed to expose the plurality of filled vias 812. In some embodiments, removing the lower portion 1110 of the substrate 200 is performed via a grind process and a planarization process.

In some embodiments, the method 100 includes forming a backside RDL 1210 on a lower surface 1220 of the substrate 200 after removing the lower portion 1110 of the substrate 200, as shown in FIG. 12. In some embodiments, the method 100 includes removing the carrier plate 1020 after forming the backside RDL 1210. FIG. 13 depicts a side view of a portion of the substrate 200 after removing the carrier plate 1020 in accordance with at least some embodiments of the present disclosure.

The methods provided herein may be performed in multiple process chambers. For example, in some embodiments, forming the first patterned mask 202, etching the exposed portions 210 of the substrate, depositing the seed layer 702, and filling the plurality of blind vias 310 are performed in separate process chambers. The first patterned mask 202 and the second patterned mask 404 may be formed in a lithography chamber. The seed layer 702 may be deposited in a PVD chamber. The filling of the plurality of blind vias 310 may be performed in a plating chamber. In some embodiments, multiple processes of the methods provided herein may be performed in the same chamber.

While the foregoing is directed to embodiments of the present disclosure, other and further embodiments of the disclosure may be devised without departing from the basic scope thereof.

1. A method of processing a substrate, comprising:
forming a first patterned mask on an upper surface of a substrate made of glass, wherein openings of the first patterned mask expose portions of the substrate;
etching the exposed portions of the substrate to form a plurality of blind vias;
removing the first patterned mask;
forming a second patterned mask on the substrate after removing the first patterned mask, wherein openings of the second patterned mask expose second portions of the substrate;
etching the exposed second portions of the substrate to form a redistribution layer (RDL) pattern at an upper portion of at least one of the plurality of blind vias;
depositing a seed layer in the plurality of blind vias and the RDL pattern; and
filling the plurality of blind vias and the RDL pattern with a metal material to form a plurality of filled vias and a redistribution layer (RDL).

2. The method of claim 1, further comprising performing a planarization process on the upper surface of the substrate after forming the plurality of filled vias, wherein after the planarization process, a first set of the plurality of filled vias remain electrically coupled via the RDL pattern.

3. The method of claim 2, further comprising:
forming a second RDL on the upper surface of the substrate; and
attaching a carrier plate to the second RDL prior to removing the lower portion of the substrate.

4. The method of claim 3, wherein the carrier plate is made of glass or metal.

5. The method of claim 3, further comprising forming a backside RDL on a lower surface of the substrate after removing the lower portion of the substrate.

6. The method of claim 1, wherein filling the plurality of blind vias is performed via a plating process.

7. The method of claim 1, further comprising removing a lower portion of the substrate to expose a lower end of the plurality of filled vias.

8. The method of claim 1, wherein the plurality of blind vias have a diameter of less than about 20 microns.

9. The method of claim 1, wherein removing the lower portion of the substrate is performed via a grind process and a planarization process.

10. The method of claim 1, wherein the seed layer and the metal material comprise copper.

11. The method of claim 1, wherein etching the exposed portions comprises a dry etch.

12. The method of claim 1, wherein etching does not include laser drilling.

13. A method of processing a substrate, comprising:
etching the substrate to form a plurality of blind vias;
etching the substrate to form a redistribution layer (RDL) pattern at an upper portion of at least one of the plurality of blind vias;
depositing a seed layer in the plurality of blind vias and the RDL pattern; and
filling the plurality of blind vias and the RDL pattern with a metal material to form a plurality of filled vias and a redistribution layer (RDL).

14. The method of claim 13, further comprising forming a second RDL on the RDL and a backside RDL on a lower surface of the substrate.

15. The method of claim 13, further comprising, prior to forming the plurality of blind vias, forming a first patterned mask via lithography on an upper surface of the substrate.

16. The method of claim 13, wherein the substrate has a thickness of about .8 to about 1.3 mm.

17. The method of claim 13, further comprising, after filling the plurality of blind vias, removing a lower portion of the substrate to expose a lower end of the plurality of filled vias; and attaching a carrier plate to the substrate prior to removing the lower portion of the substrate.

18. The method of claim 13, wherein the seed layer is deposited via a physical vapor deposition process.

19. The method of claim 13, wherein etching the substrate to form the plurality of blind vias and the form the RDL pattern is performed via a dry etch process.

20. The method of claim 13, wherein etching the substrate, depositing the seed layer, and filling the plurality of blind vias are performed in separate process chambers.
